(19) United States
(12) Patent Application Publication
(10) Pub. No.: US 2026/0100727 A1
(43) Pub. Date: Apr. 9, 2026

(54) TIME-DIVISION DUPLEXING RADIO TRANSCEIVER

(71) Applicant: Realtek Semiconductor Corp., Hsinchu (TW)

(72) Inventor: Chia-Liang (Leon) Lin, Fremont, CA (US)

(21) Appl. No.: 18/905,188

(22) Filed: Oct. 3, 2024

(51) Int. Cl. H04B 1/40; H03F 1/56; H03F 3/24; H04L 5/14

(52) U.S. Cl. CPC H04B 1/40; H03F 1/565; H03F 3/245; H03F 2200/222; H03F 2200/294; H03F 2200/387; H03F 2200/451; H04L 5/14

(57) ABSTRACT

A TDD (time-division duplexing) radio transceiver includes: a PA (power amplifier) that processes a first signal and delivers a second signal; an LNA (low-noise amplifier) that processes a fourth signal and delivers a fifth signal; an antenna interfacing with a third signal; and a co-matching network with a first inductor receiving the first signal, a second inductor establishing the third signal, a third inductor in series with a first capacitor and a first switch controlled by a first logical signal providing a shunt path for the third signal, a fourth inductor linking the third signal to the fourth signal, and a second switch controlled by the logical signal to short the fourth signal to ground, wherein the first, second, and third inductors are strongly mutually coupled.

### BACKGROUND OF THE INVENTION

### Field of the Invention

The present invention pertains to radio transceivers, and more specifically to of time-division duplexing radio transceivers.

### Description of Related Art

FIG. 1 illustrates a TDD (time-division duplexing) radio transceiver 100 featuring power amplifier (PA) 110, low-noise amplifier (LNA) 120, co-matching network 130, and antenna 140. Radio transceiver 100 acts as a transmitter when a transmitter-enabling signal ENTX is 1 and as a receiver when a receiver-enabling signal ENRX is 1, whereas ENTX and ENRX cannot be both 1 at the same time. With ENTX as 1, PA 110 processes a TX input signal from a preceding circuit and through co-matching network 130 converts into an antenna signal to be transmitted by antenna 140. When ENRX is 1, LNA 120 processes an antenna signal from antenna 140 via co-matching network 130 and delivers an RX output signal to a subsequent circuit. The co-matching network 130 facilitates the sharing of the same antenna between PA 110 and LNA 120, which reduces but does not completely remove the loading effects of LNA 120 on PA 110.

What is desired is a co-matching network that helps to alleviate the loading effects of LNA on PA, but also can enhance performance of PA.

### BRIEF SUMMARY OF THIS INVENTION

An objective of this invention is to establish a co-matching network for a TDD (time-division duplexing) radio transceiver containing both a transmitter and receiver, reducing the receiver's loading effect on the transmitter and enhancing the transmitter's performance by utilizing mutual coupling of inductors.

A TDD (time-division duplexing) radio transceiver includes: a PA (power amplifier) that processes a first signal and delivers a second signal; an LNA (low-noise amplifier) that processes a fourth signal and delivers a fifth signal; an antenna interfacing with a third signal; and a co-matching network with a first inductor receiving the first signal, a second inductor establishing the third signal, a third inductor in series with a first capacitor and a first switch controlled by a logical signal providing a shunt path for the third signal, a fourth inductor linking the third signal to the fourth signal, and a second switch controlled by the logical signal to short the fourth signal to ground, where the first, second, and third inductors are strongly mutually coupled.

### BRIEF DESCRIPTION OF THE DRAWINGS

FIG. 1 presents a schematic of a functional block diagram of a TDD (time-division duplexing) radio transceiver.

FIG. 2 presents a schematic of a schematic diagram of a TDD (time-division duplexing) radio transceiver in accordance with an embodiment of the present invention.

FIG. 3 depicts a top view of an exemplary layout of three strongly coupled inductors of the co-matching network of the TDD radio transceiver of FIG. 2.

FIG. 4 depicts a power amplifier that can be used in the radio transceiver of FIG. 2.

FIG. 5 depicts a low-noise amplifier that can be used in the radio transceiver of FIG. 2.

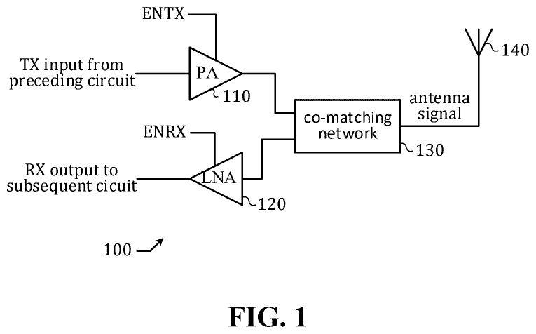

### DETAILED DESCRIPTION OF THIS INVENTION

The present invention relates to radio transceivers. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

Persons of ordinary skill in the art understand terms and basic concepts related to microelectronics that are used in this disclosure, such as “voltage,” “current,” “signal,” “frequency,” “differential signal,” “capacitor,” “inductor,” “resistor,” “transistor,” “MOST (metal-oxide semiconductor field-effect transistor),” “PMOST (p-channel metal oxide semiconductor field-effect transistor),” “NMOST (n-channel metal oxide semiconductor field-effect transistor),” “AC (alternating current),” “DC (direct current),” “source,” “gate,” “drain,” “node,” “ground node,” “power supply node,” “cascode,” “amplifier,” “common-source,” “common-gate,” “reactance,” and “impedance.” For brevity, in this present disclosure, “field effect transistor” is simply referred to as “transistor.” Individuals with ordinary skill in the field can identify symbols for an inductor, capacitor, switch, NMOS transistor, and PMOS transistor, and can identify “source,”“gate,”and “drain”of MOS transistor, for both NMOS and PMOS. Terms and basic concepts like these are apparent to those of ordinary skill in the art and thus will not be explained in detail here. Those of ordinary skill in the field are able to interpret schematics and understand the interconnections between circuit elements with no need for elaborate explanations.

A signal is either a voltage or current of a variable level that carries certain information and can vary with time. The level of the signal at a moment represents the state of the signal at that moment. A signal is a “voltage signal” (“current signal”) if it is a voltage (current). In this present disclosure, since “voltage signals” appear more often than “current signals,” for brevity a “signal” refers to a “voltage signal” unless it is otherwise specified as a “current signal.”

In this document, the abbreviation “DC” refers to direct current, while “AC” denotes alternating current. Any signal may be broken down into a DC part, which is essentially constant, and an AC part, which is largely characterized by its fluctuation.

A DC node is a node of a substantially fixed electric potential. In particular, “V_{DD}” denotes a special DC node referred to as a power node. A ground node is a special DC node of zero voltage (0V).

A logical signal has two states: low (0) and high (1). When “Q is high” or “Q is low” is stated, it means Q is in its respective 1 or 0 state. A logical signal can be used to either turn on or turn off a function; the state that leads to the turn-on of the function is referred to as the “on state.”

A switch operates based on a logical signal, acting as a short circuit when the signal is 1 and an open circuit when it's 0.

Throughout this disclosure, differential (signal) embodiment is widely used, wherein a signal comprises a first voltage and a second voltage denoted with suffixes “+” and “−¿,” respectively, attached in subscript, and the first voltage and the second voltage have the same DC component but opposite AC component. For instance, a signal V₁ in a differential embodiment comprises two voltages V_{1+¿¿} and V_{1-¿¿}, wherein V_{1+¿¿} and V_{1-¿¿} have the same DC component but opposite AC components.

A MOST (metal-oxide semiconductor field-effect transistor) is an active device with source, gate, and drain terminals that can act as an amplifier. There are NMOST (n-channel) and PMOST (p-channel) transistors. A MOST operates in the “saturation region” and can act effectively as an amplifier when the gate-to-source voltage exceeds a certain threshold voltage, but the gate-to-drain voltage is lower than the threshold. It functions as a switch in the “triode region”when both voltages are higher than the threshold.

A MOST can be configured as a common-source amplifier that converts an input voltage received from its gate into an output current delivered via its drain, while its source is usually connected to a sufficiently low-impedance node so that a voltage at its source can remain approximately fixed regardless of a dynamic nature of the input voltage.

A MOST can also be configured as a common-gate amplifier that receives an input current from its source and delivers an output current via its drain, while its gate is usually connected to a sufficiently low-impedance node so that a voltage at its gate can remain approximately fixed regardless of a dynamic nature of the input current. A common-gate amplifier can effectively relay the input (source) current into the output (drain) current.

In a “cascode” configuration, one MOST is stacked upon another, combining common-source and common-gate amplifiers and forming a “cascode amplifier.” This setup ensures good reverse isolation, minimizing the impact of drain load changes on the first MOST.

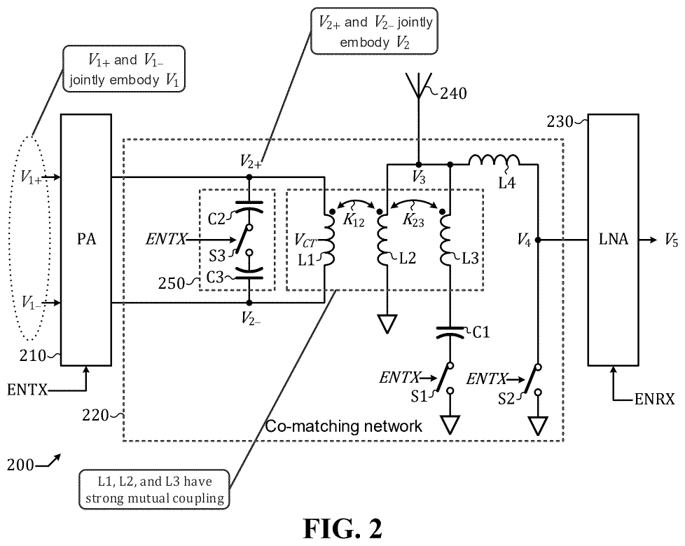

A schematic diagram of a TDD radio transceiver 200 in accordance with an embodiment of the present invention is shown in FIG. 2. TDD radio transceiver 200 includes: a PA (power amplifier) 210 that receives a first signal V₁ (jointly embodied by two voltages V_{1+¿¿} and V_{1-¿¿} in differential embodiment) and outputs a second signal V₂ (jointly embodied by two voltages V_{2+¿¿} and V_{2-¿¿} in differential embodiment); an LNA (low-noise amplifier) 230 that receives a fourth signal V₄ and outputs a fifth signal V₅; an antenna 240 interfacing with a third signal V₃; and a co-matching network 220 including a first inductor L1 (with a center tap of voltage V_{CT}) connecting to V₂, a second inductor L2 establishing V₃, a third inductor L3 in series with a first capacitor C1 and a first switch S1 controlled by a transmitter-enabling signal ENTX to form a shunt path of V₃, a fourth inductor L4, and a second switch S2 controlled by ENTX to short V₄ to ground. Inductors L1, L2, and L3 have strong mutual coupling. PA 210 is controlled by ENTX. When ENTX is 1, radio transceiver 200 is in a transmitter mode, PA 210 is turned on to amplify V₁ into V₂ that is established across L1.

A strong mutual coupling K₁₂ between L1 and L2 effectively transforms V₂ into V₃ that is established across L2 and radiated by antenna 240 to the air. L4 is used for impedance matching of LNA 230, which is controlled by a receiver-enabling signal ENRX. When ENRX is 1, radio transceiver 200 is in a receiver mode and LNA 230 is turned on to amplified V₄ into V₅. ENTX and ENRX cannot be both 1 at the same time. When EXTX is 1, V₃ may have a large swing, but V₄ is shorted to ground through S2 to prevent V₄ from having a large swing that could damage LNA 230. However, in the transmitter mode L4 is an inductive loading to V₃ and needs to be compensated by a capacitive load. L3 in series with C1 can form an effective capacitive load if C1 has a larger reactance (in magnitude) than L3. Inductance of L3 and capacitance of C1 are chosen such that the series connection of L3 and C1 forms a capacitive load to compensate the inductive load of L4. A strong mutual coupling K₂₃ between L2 and L3 can enhance the magnetic flux linkage of L2 and make the transform from V₂ to V₃ more efficient and thus improve the transmitter performance. In other words, L3 serves two purposes at the same time: first, by connecting in series with C1 it forms a capacitive load to compensate the inductive load of L4; second, by strong mutual coupling to L2 it enhances the transform from V₂ to V₃.

In a further embodiment, radio transceiver 200 further includes a switch-capacitor network 250 comprising a second capacitor C2, a third capacitor C3, and a third switch S3 controlled by ENTX. When ENTX is 1, C3 and C2 are effectively connected in series to present a capacitive load that compensates the inductive load of L1 to boost an impedance seen by PA 210 and thus enhance a gain.

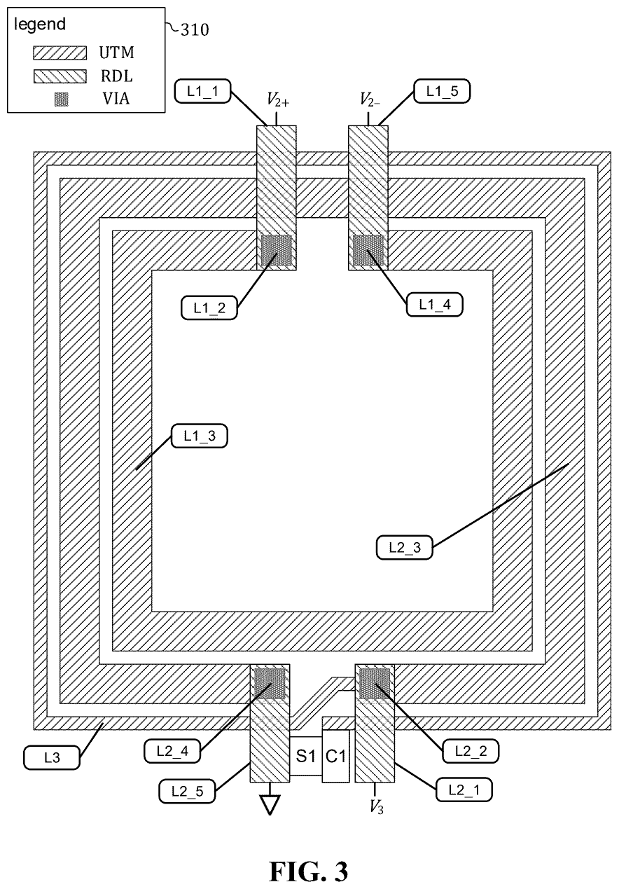

By way of example but not limitation, radio transceiver 200 is fabricated on a silicon substrate using CMOS (complementary metal-oxide semiconductor) process technology, featuring a multi-layer structure with active device layers and several metal layers, including a UTM (ultra-thick metal) layer, a RDL (re-distribution layer), and a few lower metal layers. A top view of an exemplary layout of L1, L2, and L3 are shown in FIG. 3. A legend is shown in box 310. Note that “VIA” is a layer sandwiched between UTM and RDL and used for inter-metal connection. L1, L2, and L3 are laid out closely in a concentric manner. The layout of L1 includes L1_1 on RDL, L1_2 on VIA, L1_3 on UTM, L1_4 on VIA, and L1_5 on RDL, wherein L1's two ends L1_1 and L1_5 connect to V_{2+¿¿} and V_{2-¿¿}, respectively. The layout of L2 includes L2_1 on RDL, L2_2 on VIA, L2_3 on UTM, L2_4 on VIA, and L2_5 on RDL, wherein L2's two ends L2_1 and L2_5 connect to V₃ and the ground, respectively. L3 is laid out on UTM, connects to L2_2 on one end, and to L2_5 on the other end through the series connection of C1 and S1, which will be laid out on lower metal layers and active device layers.

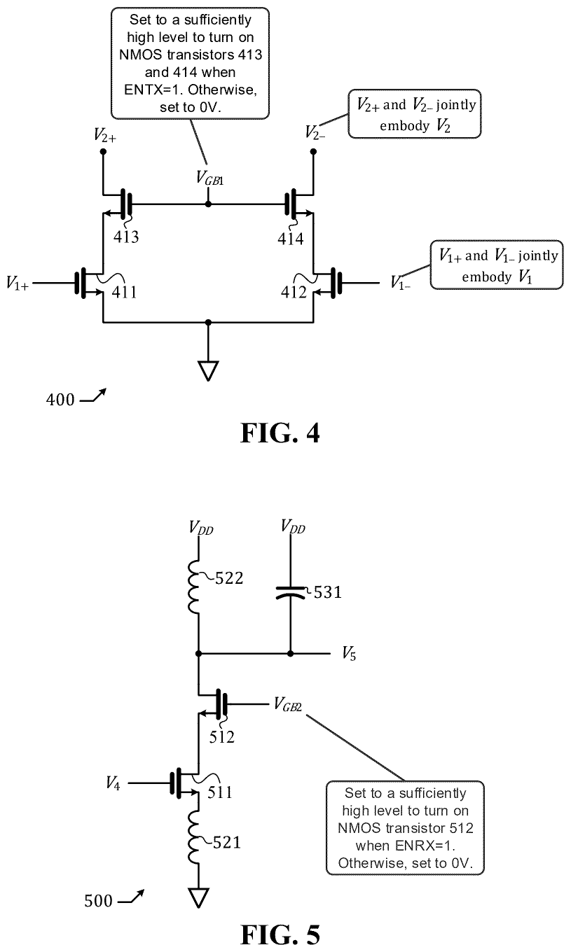

FIG. 4 shows a cascode amplifier 400 that can be used to embody PA 210 of FIG. 2. Cascode amplifier 400 includes NMOS transistors 411 and 413 configured as a cascode amplifier to amplify V_{1+¿¿} into V_{2+¿¿}, and NMOS transistors 412 and 414 configured as a cascode amplifier to amplify V_{1-¿¿} into V_{2-¿¿}. NMOS transistors 413 and 414 are controlled by a gate bias voltage V_{GB1}. L1 is placed across V_{2+¿¿} and V_{2-¿¿} (see FIG. 2), therefore V_{2+¿¿} and V_{2-¿¿} have the same DC level as that of V_{CT}, which is the voltage at the center tap of L1. Circuit topology wise, cascode amplifier 400 is well known in the prior art and thus not explained in detail here. When ENTX is 1, V_{GB1} is set to a sufficiently high level to turn on NMOS transistors 413 and 414, enabling the amplifier function. Additionally, in terms of DC level, V_{CT} is higher than V_{GB1} minus the threshold voltage of NMOS transistors 413 and 414, ensuring both transistors stay in the “saturation region” and work effectively. When ENTX is 0, V_{GB1} is tied to the ground (i.e. set to 0V) to turn off NMOS transistors 413 and 414, turning off the amplifier function.

A LNA 500 that can be used to embody LNA 230 of FIG. 2 is shown in FIG. 5. LNA 500 comprises two NMOS transistors 511 and 512, a source-degenerating inductor 521, a load inductor 522, and a load capacitor 531. NMOS transistor 512 is controlled by a gate bias voltage V_{GB2}. NMOS transistors 511 and 512 are stacked up to form a cascode amplifier, while source-degenerating inductor 521 provides inductive source degeneration. Load inductor 522 and load capacitor 531 form a resonant network to present a high impedance to boost a gain of LNA 500. Circuit topology wise, LNA 500 is well known in the prior art and thus not explained in detail here. When ENRX is 1, V_{GB2} is set to a sufficiently high level to turn on NMOS transistors 512, enabling the amplifier function, while the power supply “V_{DD}” is higher than V_{GB2} minus the threshold voltage of NMOS transistor 512 to ensure NMOS transistor 512 operating in the saturation region. When ENRX is 0, V_{GB2} is tied to the ground (i.e. set to 0V) to turn off NMOS transistor 512, disabling the amplifier function.

Those skilled in the art can choose to add an additional transistor to the transistor stack-up topology to enhance reverse isolation or to reduce stress on neighboring transistors, besides what is described in the present disclosure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A TDD (time-division duplexing) radio transceiver including:
a PA (power amplifier) that processes a first signal and delivers a second signal;
an LNA (low-noise amplifier) that processes a fourth signal and delivers a fifth signal;
an antenna interfacing with a third signal; and
a co-matching network with a first inductor receiving the first signal, a second inductor establishing the third signal, a third inductor in series with a first capacitor and a first switch controlled by a first logical signal providing a shunt path for the third signal, a fourth inductor linking the third signal to the fourth signal, and a second switch controlled by the logical signal to short the fourth signal to ground, wherein the first, second, and third inductors are strongly mutually coupled.

2. The TDD radio transceiver of claim 1, wherein the first, second, and third inductors are laid out closely in a concentric manner.

3. The TDD radio transceiver of claim 1 further comprising a switch-capacitor network comprising a serial connection of a second capacitor and a third switch controlled by the first logical signal.

4. The TDD radio transceiver of claim 1, wherein a reactance of the third inductor is smaller than a reactance of the first capacitor in magnitude.

5. The TDD radio transceiver of claim 1, wherein the PA is managed by the first logical signal, allowing all of the PA, the first switch, and the second switch to be either turned on simultaneously or turned off together.

6. The TDD radio transceiver of claim 5, wherein the PA comprises a stack up of a second MOS (metal-oxide semiconductor) transistor upon a first MOS transistor to form a cascode amplifier, a DC (direct current) level of a gate of the second MOS transistor is being controlled by the first logical signal to either turn on or turn off the second MOS transistor.

7. The TDD radio transceiver of claim 1, wherein the LNA is controlled by a second logical signal, which cannot be in the on state simultaneously with the first logical signal.

8. The TDD radio transceiver of claim 7, wherein the LNA comprises a stack up of a second MOS (metal-oxide semiconductor) transistor upon a first MOS transistor to form a cascode amplifier, a source-degenerating inductor, a load inductor, and a load capacitor, a DC (direct current) level of a gate of the second MOS transistor being controlled by the second logical signal to either turn on or turn off the second MOS transistor.
